(19) United States
(12) Patent Application Publication
(10) Pub. No.: US 2026/0142647 A1
(43) Pub. Date: May 21, 2026

(54) ACOUSTIC WAVE FILTER AND MULTIPLEXER

(71) Applicant: Murata Manufacturing Co., Ltd., Nagaokakyo-shi (JP)

(72) Inventor: Shiori ASAKAWA, Nagaokakyo-shi (JP)

(21) Appl. No.: 19/386,579

(22) Filed: Nov. 12, 2025

(30) Foreign Application Priority Data
Nov. 19, 2024 (JP) 2024-201776

(51) Int. Cl. H03H 9/56; H03H 9/13; H03H 9/54; H03H 9/70

(52) U.S. Cl. CPC H03H 9/568; H03H 9/133; H03H 9/542; H03H 9/703

(57) ABSTRACT

An acoustic wave filter includes a filter circuit on a first path connecting an input terminal and an output terminal, and an additional circuit on a second path connected in parallel with the first path. The filter circuit includes series arm resonators on the first path. First and second nodes, which are connection points between the first and second paths, are provided on both outer sides of the series arm resonators, and the first node is closer to the input terminal than the second node. The series arm resonator, which is closer to the output terminal than the first node, includes one or more IDT electrodes, and an electrode finger pitch of the IDT electrode connected to the first node, among the one or more IDT electrodes, is smaller than the electrode finger pitches of the IDT electrodes of the other series arm resonators.

### CROSS REFERENCE TO RELATED APPLICATIONS

This application claims the benefit of priority to Japanese Patent Application No. 2024-201776 filed on Nov. 19, 2024. The entire contents of this application are hereby incorporated herein by reference.

### BACKGROUND OF THE INVENTION

### 1. Field of the Invention

The present invention relates to acoustic wave filters and multiplexers including the acoustic wave filters.

### 2. Description of the Related Art

Heretofore, an acoustic wave filter including a plurality of acoustic wave resonators is known. As an example of this type of acoustic wave filter, International Publication No. 2022/181578 discloses an acoustic wave filter including a filter circuit having a predetermined frequency band as a pass band and an additional circuit (cancellation circuit) connected in parallel with the filter circuit. Each of the filter circuit and the additional circuit includes an acoustic wave resonator including an interdigital transducer (IDT) electrode.

### SUMMARY OF THE INVENTION

The acoustic wave filter disclosed in International Publication No. 2022/181578 has a problem in that the power consumption of the additional circuit is high. For example, when the power consumption of the additional circuit is high, the electrode fingers of an IDT electrode included in the additional circuit may melt.

Example embodiments of the present invention provide acoustic wave filters that reduce the power consumption of an additional circuit.

An acoustic wave filter according to an example embodiment of the present invention includes an input terminal, an output terminal, a filter circuit on a first path connecting the input terminal and the output terminal, and an additional circuit on a second path connected in parallel with at least a portion of the first path. The additional circuit includes a longitudinally coupled acoustic wave resonator. The filter circuit includes a plurality of series arm resonators on the first path and one or more parallel arm resonators on a path connecting the first path and ground. Each of the plurality of series arm resonators and the one or more parallel arm resonators includes an IDT electrode. A first node and a second node, which are connection points between the first path and the second path, are provided on both outer sides of one or more of the series arm resonators on the first path. The first node is closer to the input terminal than the second node. One of the plurality of series arm resonators that is connected to the first node and is closer to the output terminal than the first node includes one or more IDT electrodes. An electrode finger pitch of one of the one or more IDT electrodes that is connected to the first node is smaller than an electrode finger pitch of IDT electrodes of other series arm resonators excluding the one of the plurality of series arm resonators.

An acoustic wave filter according to an example embodiment of the present invention includes an input terminal, an output terminal, a filter circuit on a first path connecting the input terminal and the output terminal, and an additional circuit on a second path connected in parallel with at least a portion of the first path. The additional circuit includes a longitudinally coupled acoustic wave resonator. The filter circuit includes a plurality of series arm resonators on the first path and one or more parallel arm resonators on a path connecting the first path and ground. Each of the plurality of series arm resonators and the one or more parallel arm resonators includes an IDT electrode. A first node and a second node, which are connection points between the first path and the second path, are provided on both outer sides of one or more of the series arm resonators on the first path. The first node is closer to the input terminal than the second node and is located between two of the series arm resonators that are adjacent to each other on the first path. One of the two series arm resonators located closer to the output terminal than the first node includes one or more IDT electrodes. An electrode finger pitch of one of the one or more IDT electrodes that is connected to the first node is smaller than an electrode finger pitch of an IDT electrode of a series arm resonator connected to the first node and located closer to the input terminal than the first node.

A multiplexer according to an example embodiment of the present invention includes the above-described acoustic wave filter and another filter including a circuit that is different from the filter circuit.

With acoustic wave filters and multiplexers according to example embodiments 4 present invention, the power consumption of an additional circuit is reduced.

The above and other elements, features, steps, characteristics and advantages of the present invention will become more apparent from the following detailed description of the example embodiments with reference to the attached drawings.

### BRIEF DESCRIPTION OF THE DRAWINGS

FIG. 1 is a circuit configuration diagram illustrating a filter circuit and an additional circuit of an acoustic wave filter according to Example Embodiment 1 of the present invention.

FIG. 2 is a plan view and a cross-sectional view schematically illustrating the electrode configuration of an acoustic wave resonator of a filter circuit.

FIG. 3 is a plan view schematically illustrating the electrode configuration of a longitudinally coupled acoustic wave resonator of the additional circuit.

FIG. 4 is a diagram illustrating electrode parameters of IDT electrodes of the acoustic wave filter of Example Embodiment 1 of the present invention.

FIG. 5 is a diagram illustrating electrode parameters of IDT electrodes of an acoustic wave filter of a Comparative Example.

FIG. 6 is a schematic diagram illustrating the resonant frequency and so forth of a series arm resonator included in the filter circuit.

FIG. 7 is a diagram illustrating power consumption of additional circuits of acoustic wave filters of Example Embodiment 1 and the Comparative Example.

FIG. 8 is a diagram illustrating attenuation outside the pass band of the acoustic wave filters of Example Embodiment 1 and the Comparative Example.

FIG. 9 is a diagram illustrating a portion of an IDT electrode of a filter circuit of Modification 1 of Example Embodiment 1 of the present invention.

FIG. 10 is a diagram illustrating a portion of an IDT electrode of an additional circuit of Modification 1 of Example Embodiment 1 of the present invention.

FIG. 11 is a diagram illustrating electrode parameters of IDT electrodes of Modification 1 of Example Embodiment 1 of the present invention.

FIG. 12 is a circuit configuration diagram illustrating a filter circuit and an additional circuit of an acoustic wave filter according to Modification 2 of Example Embodiment 1 of the present invention.

FIG. 13 is a circuit configuration diagram illustrating a filter circuit and an additional circuit of an acoustic wave filter according to Modification 3 of Example Embodiment 1 of the present invention.

FIG. 14 is a circuit configuration diagram of a multiplexer according to Example Embodiment 2 of the present invention.

### DETAILED DESCRIPTION OF THE EXAMPLE EMBODIMENTS

Hereinafter, example embodiments of the present invention will be described in detail with reference to drawings. The example embodiments described hereafter each illustrate a comprehensive or specific example of the present invention. The numerical values, shapes, materials, components, arrangement of the components, the ways in which the components are connected to each other and so forth given in the following example embodiments are merely examples and are not intended to limit the present invention. Components not described in the independent claims among components in the following example embodiments are described as optional components. In addition, the sizes of the components illustrated in the drawings and the ratios between the sizes are not necessarily strictly accurate. Furthermore, in the drawings, portions of configurations that are substantially the same as each other are denoted by the same symbols and repeated description thereof may be omitted or simplified. In addition, in the following example embodiments, “connected” is not limited to only the case of being directly connected and also includes the case of being electrically connected via another element or the like.

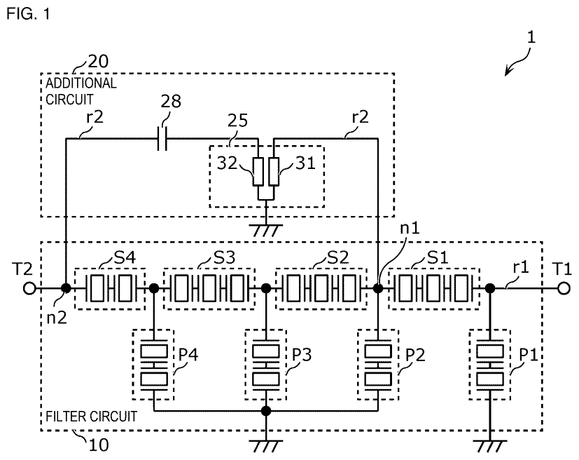

The configuration of an acoustic wave filter according to Example Embodiment 1 will be described with reference to FIGS. 1 to 4.

FIG. 1 is a circuit configuration diagram illustrating a filter circuit 10 and an additional circuit 20 of an acoustic wave filter 1 according to Example Embodiment 1.

As illustrated in FIG. 1, the acoustic wave filter 1 includes the filter circuit 10 and the additional circuit 20. The acoustic wave filter 1 also includes an input terminal T1 and an output terminal T2.

The input terminal T1 is a terminal to which a radio-frequency signal is input. For example, the input terminal T1 is connected to an RF signal processing circuit (not illustrated) via an amplifier circuit and so forth (not illustrated). The output terminal T2 is a terminal from which a radio-frequency signal is output. For example, the output terminal T2 is connected to an antenna element (not illustrated).

The filter circuit 10 is disposed on a first path r1 connecting the input terminal T1 and the output terminal T2. The filter circuit 10 has a pass band that is a predetermined frequency band defined by a communication standard. The acoustic wave filter 1 including the filter circuit 10 is, for example, a transmission filter with a pass band is an uplink frequency band (transmission band).

The additional circuit 20 is a cancellation circuit having a cancelling component of the same amplitude and opposite phase to the filter circuit 10. The additional circuit 20 is provided on a second path r2 connected in parallel with at least a portion of the first path r1. The additional connection of the additional circuit 20 to the filter circuit 10 makes it possible to improve the attenuation characteristics outside the pass band of the filter circuit 10.

Next, the connection relationship between the acoustic wave resonators included in the filter circuit 10 and the additional circuit 20 will be described.

As illustrated in FIG. 1, the filter circuit 10 includes series arm resonators S1, S2, S3, and S4 and parallel arm resonators P1, P2, P3, and P4, which are acoustic wave resonators.

The series arm resonators S1 to S4 are disposed on the first path r1 connecting the input terminal T1 to the output terminal T2. The series arm resonators S1 to S4 are connected in series in this order from the input terminal T1 to the output terminal T2.

The parallel arm resonators P1 to P4 are each disposed on a path connecting a node between the input terminal T1 and the series arm resonators S1 to S4 disposed on the first path r1 to the ground (reference terminal). Specifically, among the parallel arm resonators P1 to P4, the parallel arm resonator P1, which is closest to the input terminal T1, has one end connected to a node between the input terminal T1 and the series arm resonator S1, and the other end connected to the ground. One end of the parallel arm resonator P2 is connected to a node between the series arm resonator S1 and the series arm resonator S2 (first node n1 described later). One end of the parallel arm resonator P3 is connected to a node between the series arm resonator S2 and the series arm resonator S3. One end of the parallel arm resonator P4 is connected to a node between the series arm resonator S3 and the series arm resonator S4. The other ends of the parallel arm resonators P2, P3, and P4 are all connected to the ground by wiring.

Thus, the filter circuit 10 has a n-type ladder filter structure including the four series arm resonators S1 to S4 disposed on the first path r1 and the four parallel arm resonators P1 to P4 disposed on the paths connecting the first path r1 to the ground. Note that the number of series arm resonators and the number of parallel arm resonators of the filter circuit 10 are not limited to four, and it is acceptable that there are two or more series arm resonators and one or more parallel arm resonators. An inductor may be provided between each parallel arm resonator and the ground.

Each acoustic wave resonator may be a single resonator including one IDT electrode, or may be a plurality of split resonators including a plurality of IDT electrodes. The plurality of split resonators may be a plurality of split resonators connected in series with each other, or a plurality of split resonators connected in parallel with each other.

A plurality of split resonators connected in series with each other refers to acoustic wave resonators in which a connection node between adjacent split resonators connected in series with each other is not connected to anything other than the adjacent split resonators. For example, no other element is connected between the adjacent split resonators, and the connection node between the adjacent split resonators is not connected to ground, etc.

The first node n1 and a second node n2, which are connection points between the first path r1 and the second path r2, are provided on both outer sides of the series arm resonators S2, S3, and S4 disposed on the first path r1. The first node n1 is provided closer to the input terminal T1 than the second node n2. In other words, the second node n2 is provided closer to the output terminal T2 than the first node n1.

In this example, the first node n1 is provided on the first path r1 between the series arm resonators S1 and S2, and the second node n2 is provided on the first path r1 between the series arm resonator S4 and the output terminal T2. In other words, the first node n1 is located between the two adjacent series arm resonators S1 and S2 on the first path r1, and the second node n2 is located between the series arm resonator S4 and the output terminal T2.

Note that the locations where the first node n1 and the second node n2 are provided are not limited to those described above. When the first node n1 is provided between the series arm resonators S1 and S2 as described above, the second node n2 may be provided between the series arm resonators S2 and S3 or between the series arm resonators S3 and S4. For example, when the first node n1 is provided between the input terminal T1 and the series arm resonator S1, the second node n2 may be provided between the series arm resonators S1 and S2, between the series arm resonators S2 and S3, between the series arm resonators S3 and S4, or between the series arm resonator S4 and the output terminal T2. For example, when the first node n1 is provided between the series arm resonators S2 and S3, the second node n2 may be provided between the series arm resonators S3 and S4 or between the series arm resonator S4 and the output terminal T2. For example, when the first node n1 is provided between the series arm resonators S3 and S4, the second node n2 may be provided between the series arm resonators S4 and the output terminal T2.

One end of the additional circuit 20 is connected to the first node n1, and the other end of the additional circuit 20 is connected to the second node n2. The additional circuit 20 includes a longitudinally coupled acoustic wave resonator 25, which includes a plurality of IDT electrodes, and a capacitance element 28.

The longitudinally coupled acoustic wave resonator 25 is provided on the second path r2 connecting the first node n1 and the second node n2. The capacitance element 28 is provided on the second path r2 connecting the longitudinally coupled acoustic wave resonator 25 and the second node n2. In other words, the capacitance element 28 is provided on the output terminal T2 side as viewed from the longitudinally coupled acoustic wave resonator 25.

Next, the IDT electrodes and so forth of each acoustic wave resonator of the filter circuit 10 and the additional circuit 20 will be described.

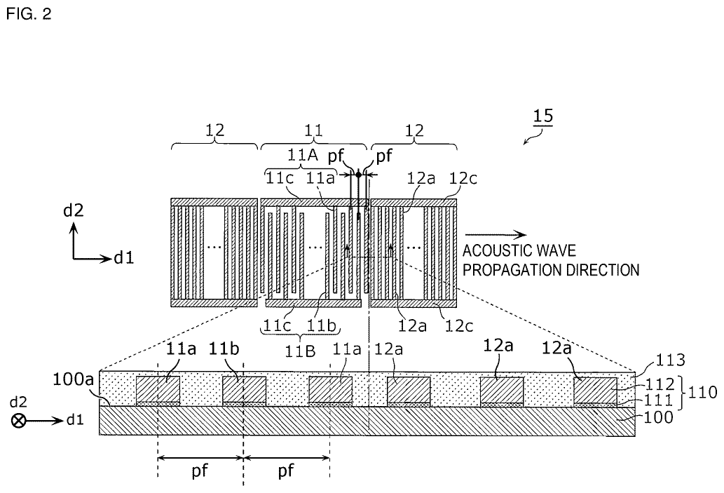

FIG. 2 is a plan view and a cross-sectional view schematically illustrating the electrode configuration of an acoustic wave resonator 15 of the filter circuit 10.

The acoustic wave resonator 15 illustrated in FIG. 2 includes a piezoelectric substrate 100, an electrode 110, and a protective film 113. The acoustic wave resonator 15 includes an IDT electrode 11 and a plurality of reflectors 12. The acoustic wave resonator 15 is a surface acoustic wave (SAW) resonator including the IDT electrode 11, the plurality of reflectors 12, and the piezoelectric substrate 100. Note that the acoustic wave resonator 15 illustrated in FIG. 2 is for explaining a typical structure, and the number, length, and so forth of the electrode fingers of the electrode are not limited to those illustrated.

The electrode 110 of the IDT electrode 11 and the plurality of reflectors 12 has a multilayer structure including an adhesive layer 111 and a main electrode layer 112, as illustrated in the cross-sectional view of FIG. 2.

The adhesive layer 111 is a layer for improving adhesion between the piezoelectric substrate 100 and the main electrode layer 112. For example, Ti is used as the material of the adhesive layer 111.

For example, Al including about 1% Cu is used as the material of the main electrode layer 112, for example.

The protective film 113 covers the electrode 110. The protective film 113 is a layer intended to, for example, protect the main electrode layer 112 from the external environment, adjust frequency-temperature characteristics, and increase moisture resistance, and is, for example, a film mainly including silicon dioxide (SiO₂).

The materials of the adhesive layer 111, the main electrode layer 112, and the protective film 113 are not limited to the above-mentioned materials. Furthermore, the electrode 110 does not necessarily have the above-mentioned multilayer structure. The electrode 110 may include, for example, a metal or alloy such as Ti, Al, Cu, Pt, Au, Ag, or Pd, or may include a plurality of multilayer bodies including any of these metals or alloys. The protective film 113 is not necessarily provided.

The material of the piezoelectric substrate 100 may be, for example, a piezoelectric material such as aluminum nitride, lithium tantalate, lithium niobate, or quartz crystal, a ceramic material such as alumina, sapphire, magnesia, silicon nitride, silicon carbide, zirconia, cordierite, mullite, steatite, or forsterite, a dielectric material such as diamond or glass, a semiconductor such as silicon or gallium nitride, or a resin, or a material including any of the above materials as a main component.

The piezoelectric substrate 100 may be a substrate including a piezoelectric layer in at least a portion thereof, or may have a multilayer structure including a piezoelectric layer. The piezoelectric substrate 100 may have a structure including, for example, a high-acoustic-velocity support substrate, a low-acoustic-velocity film, and a piezoelectric layer, and may have a structure in which the high-acoustic-velocity support substrate, the low-acoustic-velocity film, and the piezoelectric layer are stacked in this order.

As illustrated in the plan view of FIG. 2, the IDT electrode 11 of the filter circuit 10 includes a pair of comb-shaped electrodes 11A and 11B that face each other.

In this plan view, a predetermined direction along a main surface 100a of the piezoelectric substrate 100 is called a first direction d1, and a direction along the main surface 100a of the piezoelectric substrate 100 and intersecting the first direction d1 is called a second direction d2. The first direction d1 is the acoustic wave propagation direction of the acoustic wave resonator 15. In this example embodiment, the first direction d1 and the second direction d2 are perpendicular to each other.

The comb-shaped electrode 11A includes a plurality of electrode fingers 11a extending in the second direction d2 and a busbar electrode 11c connecting one ends of the plurality of electrode fingers 11a to each other. The comb-shaped electrode 11B includes a plurality of electrode fingers 11b extending in the second direction d2 and a busbar electrode 11c connecting one ends of the plurality of electrode fingers 11b to each other. The plurality of electrode fingers 11a and 11b are disposed next to each other in an alternating manner in the first direction d1 at a predetermined electrode finger pitch pf. The electrode finger pitch pf of the IDT electrode 11 is the center-to-center distance in the first direction d1 between electrode fingers 11a and 11b that are adjacent to each other in the first direction d1.

The electrode finger pitch pf is the average pitch of the plurality of electrode fingers 11a and 11b. The electrode finger pitch pf is calculated, for example, by dividing the center-to-center distance in the first direction d1 between the two electrode fingers located at the outermost ends of the IDT electrode 11 by “the total number of electrode fingers−the number of IDT electrodes”. In this example, the number of IDT electrodes is 1. That is, the electrode finger pitch pf of the IDT electrode 11 is derived as follows (Equation 1).

Electrode finger pitch=(center-to-center distance in first direction between two electrode fingers located at outermost ends of IDT electrode)/(total number of electrode fingers−number of IDT electrodes) (Equation 1)

When an acoustic wave resonator includes a plurality of split resonators, the electrode finger pitch pf is calculated by obtaining the center-to-center distance in the first direction d1 between the two electrode fingers located at the outermost ends of the IDT electrode in each of the multiple split resonators, and dividing the sum of the obtained center-to-center distances by “total number of electrode fingers-number of split resonators”. In other words, the electrode finger pitch pf in the plurality of split resonators is derived as follows (Equation 2).

Electrode finger pitch=(sum of center-to-center distances in first direction between two electrode fingers located at outermost ends of IDT electrode in each of multiple split resonators)/(total number of electrode fingers−number of split resonators) (Equation 2)

Note that “total number of electrode fingers-number of IDT electrodes” and “total number of electrode fingers-number of split resonators” can also be said to be the total number of gaps made by adjacent electrode fingers in the IDT electrodes.

The reflectors 12 are arranged on both outer sides of the IDT electrode 11 in the first direction d1. The multiple reflectors 12 include one reflector 12 located on the negative side in the first direction d1 and another reflector 12 located on the positive side in the first direction d1 when viewed from the IDT electrode 11. Each reflector 12 includes a plurality of reflecting electrode fingers 12a extending in the second direction d2, and busbar electrodes 12c connecting one ends of the plurality of reflecting electrode fingers 12a.

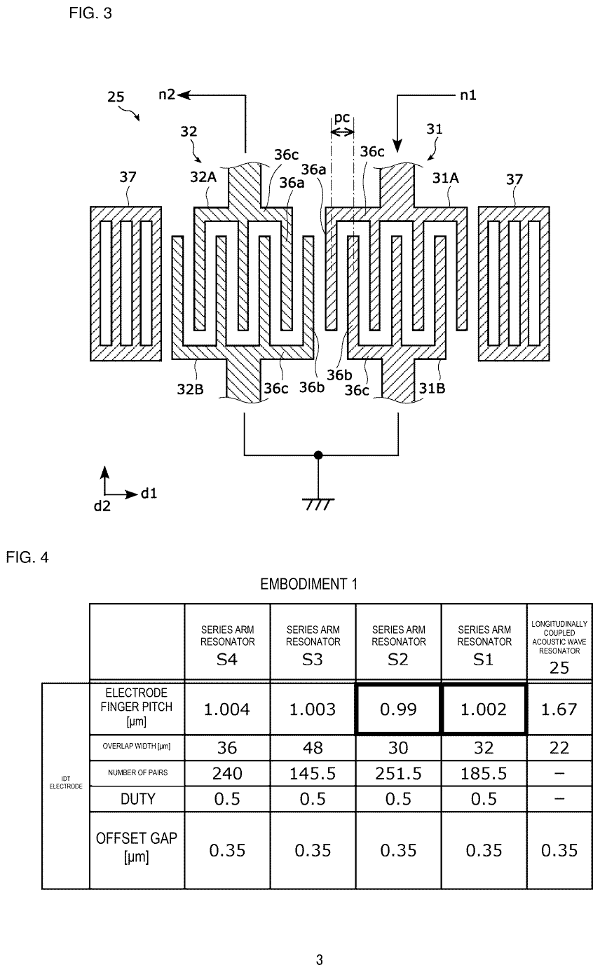

FIG. 3 is a plan view schematically illustrating the electrode configuration of the longitudinally coupled acoustic wave resonator 25 of the additional circuit 20.

The longitudinally coupled acoustic wave resonator 25 illustrated in FIG. 3 includes the piezoelectric substrate 100, the electrode 110, and the protective film 113, and includes a plurality of IDT electrodes 31 and 32 and a plurality of reflectors 37 including these components. In other words, the longitudinally coupled acoustic wave resonator 25 is a resonator including the IDT electrodes 31 and 32, the reflectors 37, and the piezoelectric substrate 100. Note that the longitudinally coupled acoustic wave resonator 25 illustrated in FIG. 3 is for explaining a typical structure, and the number, length, and so forth of the electrode fingers of the electrodes are not limited to those illustrated. The cross-sectional structure of the electrodes of the IDT electrodes 31 and 32 and the reflectors 37 is substantially the same as that of the cross-sectional view in FIG. 2.

The longitudinally coupled acoustic wave resonator 25 includes the plurality of IDT electrodes 31 and 32. The plurality of IDT electrodes 31 and 32 are disposed in this order in the first direction d1 (e.g., acoustic wave propagation direction). The additional circuit 20 also includes the plurality of reflectors 37. The plurality of reflectors 37 are located on both outer sides of the IDT electrodes 31 and 32 in the first direction d1 so that the plurality of IDT electrodes 31 and 32 are interposed therebetween.

As illustrated in FIG. 3, each of the IDT electrodes 31 and 32 of the longitudinally coupled acoustic wave resonator 25 has a comb-shaped structure. The IDT electrode 31 includes a pair of comb-shaped electrodes 31A and 31B that face each other. The IDT electrode 32 includes a pair of comb-shaped electrodes 32A and 32B that face each other.

Each of the comb-shaped electrodes 31A and 32A includes a plurality of electrode fingers 36a extending in the second direction d2 and a busbar electrode 36c connecting one ends of the plurality of electrode fingers 36a to each other. Each of the comb-shaped electrodes 31B and 32B includes a plurality of electrode fingers 36b extending in the second direction d2 and a busbar electrode 36c connecting one ends of the plurality of electrode fingers 36b to each other. The plurality of electrode fingers 36a and 36b are disposed next to each other in an alternating manner in the first direction d1 at a predetermined electrode finger pitch pc. The electrode finger pitch pc of the IDT electrodes 31 and 32 is the center-to-center distance in the first direction d1 between electrode fingers 36a and 36b that are adjacent to each other in the first direction d1.

Note that the electrode finger pitch pc is the average pitch of the plurality of electrode fingers 36a and 36b. The electrode finger pitch pc is calculated by, for example, adding together the center-to-center distance in the first direction d1 between the two electrode fingers located at the outermost ends of the IDT electrode 31 and the center-to-center distance in the first direction d1 between the two electrode fingers located at the outermost ends of the IDT electrode 32, and dividing the obtained sum by “total number of electrode fingers-number of IDT electrodes”. In this example, the number of IDT electrodes is 2. That is, the electrode finger pitch pc in the longitudinally coupled acoustic wave resonator 25 is derived as follows (Equation 3).

Electrode finger pitch=(sum of center-to-center distances in first direction between two electrode fingers located at outermost ends of IDT electrode in each of multiple IDT electrodes)/(total number of electrode fingers−number of IDT electrodes) (Equation 3)

The IDT electrode 31 is connected to the first node n1 via the second path r2 on the input terminal T1 side as viewed from the longitudinally coupled acoustic wave resonator 25. The IDT electrode 32 is connected to the second node n2 via the second path r2 on the output terminal T2 side and a capacitance element 28 as viewed from the longitudinally coupled acoustic wave resonator 25.

A radio-frequency signal input to the input terminal T1 is output from the output terminal T2 via the filter circuit 10. The additional circuit 20 reduces or prevents the output of unwanted waves from the acoustic wave filter 1 by multiplying unwanted waves outside the pass band of the filter circuit 10 with waves of the opposite phase and the same amplitude to cancel out the unwanted waves.

The electrode parameters, etc. of the IDT electrodes 11, 31, and 32 will be described.

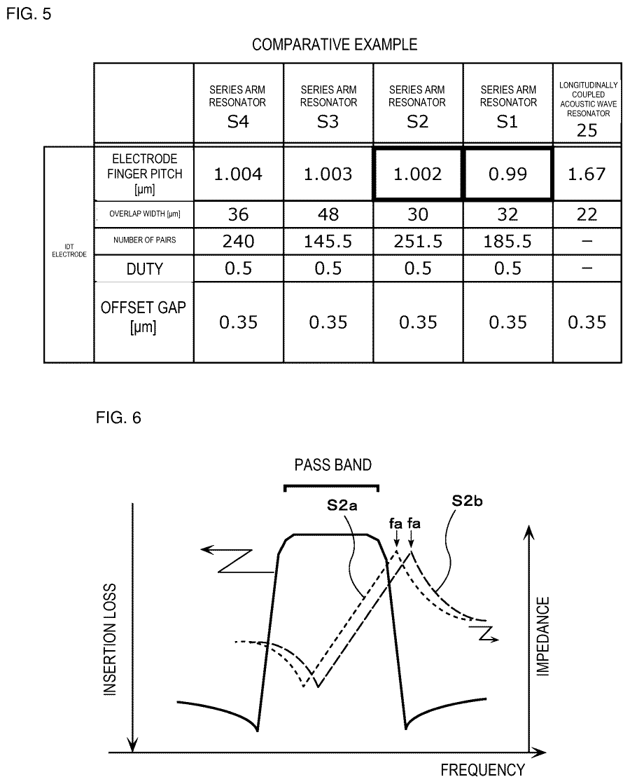

FIG. 4 is a diagram illustrating the electrode parameters of the IDT electrodes 11, 31, and 32 of the acoustic wave filter 1 of Example Embodiment 1. FIG. 5 is a diagram illustrating the electrode parameters of the IDT electrodes of an acoustic wave filter of a Comparative Example.

The basic structure of the acoustic wave filter of the Comparative Example is almost the same as that of the acoustic wave filter 1 of Example Embodiment 1 illustrated in FIGS. 1 to 3.

The electrode parameters of Example Embodiment 1 and the Comparative Example are identical in the following respects. For example, the overlap widths of the IDT electrodes of the series arm resonators S1 to S4 and the longitudinally coupled acoustic wave resonator 25 are the same in Example Embodiment 1 and the Comparative Example. The number of pairs, duty, and offset gap of each IDT electrode are also the same in Example Embodiment 1 and the Comparative Example. Example Embodiment 1 and the Comparative Example have a common point in that the electrode finger pitch pc of the IDT electrodes 31 and 32 of the longitudinally coupled acoustic wave resonator 25 is larger than the electrode finger pitches pf of the IDT electrodes 11 of the series arm resonators S1 to S4. Example Embodiment 1 and the Comparative Example have a common point in that the overlap width of the IDT electrodes 31 and 32 of the longitudinally coupled acoustic wave resonator 25 is smaller than the overlap widths of the IDT electrodes 11 of the series arm resonators S1 to S4. The overlap width is the length along which the electrode fingers 11a and 11b (or the electrode fingers 36a and 36b) overlap when the IDT electrode 11 is viewed in the first direction d1.

FIGS. 4 and 5 illustrate the electrode parameters of one of the split resonators among the plurality of split resonators of a series arm resonator. For example, the series arm resonator S2 has electrode parameters of “overlap width 30×number of pairs 251.5” for one split resonator, and is configured by connecting three of this split resonator (the same split resonator) in series with each other. The series arm resonator S4 has electrode parameters of “overlap width 36×number of pairs 240” for one split resonator, and is configured by connecting two of this split resonator in series with each other.

This example embodiment differs from the Comparative Example in the following respects. For example, in the Comparative Example, the electrode finger pitch pf of the IDT electrode 11 of the series arm resonator S2 is larger than that of the series arm resonator S1, whereas in Example Embodiment 1, the electrode finger pitch pf of the IDT electrode 11 of the series arm resonator S2 is smaller than that of the series arm resonator S1.

That is, in this example embodiment, among the multiple series arm resonators S1 and S2 disposed on the first path r1, the series arm resonator S2 connected to the first node n1 and located closer to the output terminal T2 than the first node n1 has a smaller electrode finger pitch pf in the IDT electrode 11 than the series arm resonator S1 connected to the first node n1 and located closer to the input terminal T1 than the first node n1. More specifically, the series arm resonator S2 connected to the first node n1 and located closer to the output terminal T2 than the first node n1 has the smallest electrode finger pitch pf for the IDT electrode 11 among the multiple series arm resonators S1 to S4.

Thus, by reducing the electrode finger pitch pf of the IDT electrode 11 of the series arm resonator S2 connected to the first node n1 and located closer to the output terminal T2 than the first node n1, an increase in the power consumption of the additional circuit 20 can be reduced or prevented.

FIG. 6 is a schematic diagram illustrating the resonant frequency and so forth of the series arm resonator S2 included in the filter circuit 10.

Here, the series arm resonator S2, which is connected to the first node n1 and located closer to the output terminal T2 than the first node n1, will be described as an example. Hereafter, the series arm resonator prior to changing the electrode parameters of the IDT electrode 11 will be referred to as a series arm resonator S2a, and the series arm resonator after changing the electrode parameters will be referred to as a series arm resonator S2b.

For example, when an anti-resonant frequency fa of the series arm resonator S2a is located near the maximum frequency of the pass band of the filter circuit 10 as in the series arm resonator S2a illustrated in FIG. 6, the impedance of the series arm resonator S2a at the maximum frequency is high, and it is difficult to transmit the signal at the maximum frequency toward the series arm resonator S2a side. Therefore, the above signal is transmitted from the first node n1 before the series arm resonator S2a toward the second path r2. As a result, the current flowing through the additional circuit 20 increases, and the power consumption of the additional circuit 20 increases.

In contrast, in the series arm resonator S2b illustrated in FIG. 6, the electrode finger pitch pf of the IDT electrode 11 is made smaller to shorten the wavelength of the series arm resonator S2b, and the anti-resonant frequency fa of the series arm resonator S2b is shifted toward the high frequency side. As a result, the impedance of the series arm resonator S2b at the maximum frequency of the pass band is reduced, and the signal at the maximum frequency is more easily transmitted toward the series arm resonator S2b side. As a result, the current flowing through the additional circuit 20 is prevented from becoming excessively large, and the power consumption of the additional circuit 20 can be reduced.

In the acoustic wave filter 1 of the present example embodiment, a certain series arm resonator (e.g., S2), among the plurality of series arm resonators S1 to S4, that is connected to the first node n1 and is located closer to the output terminal T2 than the first node n1, includes one or more IDT electrodes. The electrode finger pitch pf of the IDT electrode 11 connected to the first node n1, among the one or more IDT electrodes 11, is smaller than the electrode finger pitch pf of the IDT electrodes 11 of the other series arm resonators (e.g., S1, S3, and S4) excluding the certain series arm resonator S2.

As described above, by making the electrode finger pitch pf of the IDT electrode 11 of the series arm resonator S2 connected to the first node n1 smaller than the electrode finger pitch pf of the IDT electrodes 11 of the other series arm resonators S1, S3, and S4, it is possible to increase the current flowing from the upstream side to the series arm resonator S2 and reduce the current flowing to the additional circuit 20. This makes it possible to reduce the power consumption of the additional circuit 20. In addition, since the power consumption of the additional circuit 20 can be reduced, it is possible to reduce or prevent melting of the electrode fingers 36a and 36b of the IDT electrodes 31 and 32 included in the additional circuit 20.

In the acoustic wave filter 1 of this example embodiment, among the two series arm resonators S1 and S2, a certain series arm resonator S2 located closer to the output terminal T2 than the first node n1 includes one or more IDT electrodes 11. The electrode finger pitch pf of the IDT electrode 11 connected to the first node n1, among the one or more IDT electrodes 11, is smaller than the electrode finger pitch pf of the IDT electrode 11 of the series arm resonator S1 connected to the first node n1 and located closer to the input terminal T1 than the first node n1.

As described above, by making the electrode finger pitch pf of the IDT electrode 11 of the series arm resonator S2 connected to the first node n1 smaller than the electrode finger pitch pf of the IDT electrode 11 of the series arm resonator S1 located closer to the input terminal T1 than the first node n1, it is possible to increase the current flowing from the upstream side to the series arm resonator S2 and reduce the current flowing to the additional circuit 20. This makes it possible to reduce the power consumption of the additional circuit 20. In addition, since the power consumption of the additional circuit 20 can be reduced, it is possible to reduce or prevent melting of the electrode fingers 36a and 36b of the IDT electrodes 31 and 32 included in the additional circuit 20.

When a certain series arm resonator S2, which is connected to the first node n1 and located closer to the output terminal T2 than the first node n1, includes a plurality of series split resonators as in this example embodiment, the electrode finger pitch pf of the IDT electrode 11 connected to the first node n1 is derived as follows. The electrode finger pitch pf is calculated by, for example, dividing the center-to-center distance in the first direction between the two electrode fingers located at the outermost ends of the IDT electrode 11 connected to the first node n1 by “the total number of electrode fingers of the IDT electrode connected to the first node−the number of IDT electrodes connected to the first node”. In this example, the number of IDT electrodes connected to the first node n1 is 1. That is, the electrode finger pitch pf of the IDT electrode connected to the first node n1, among the plurality of IDT electrodes of the series arm resonator S2, is derived as follows (Equation 4).

Electrode finger pitch=(center-to-center distance in first direction between two electrode fingers located at outermost ends of IDT electrode connected to first node)/(total number of electrode fingers of IDT electrode connected to first node−number of IDT electrodes connected to first node) (Equation 4)

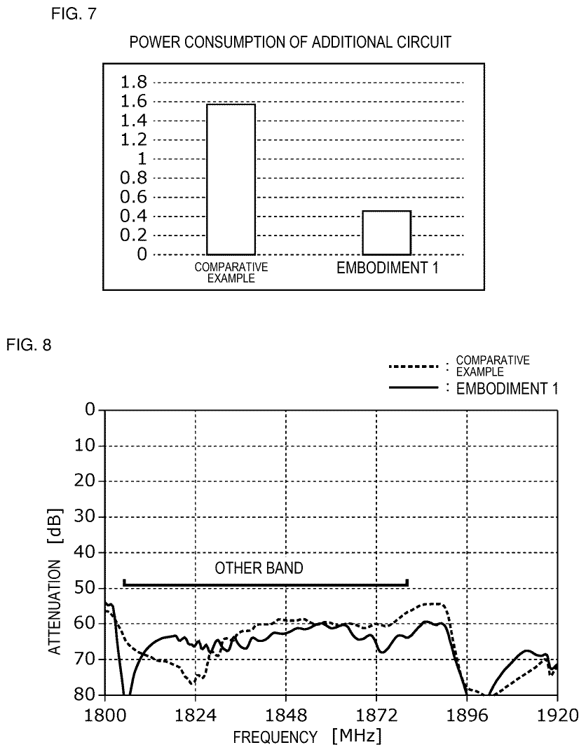

The effects of the acoustic wave filter 1 of Example Embodiment 1 will be described with reference to FIGS. 7 and 8. First, the power consumption of the additional circuit 20 will be described.

FIG. 7 is a diagram illustrating the power consumption of the additional circuit 20 of the acoustic wave filter of Example Embodiment 1 and the Comparative Example.

FIG. 7 illustrates the ratio of the power consumption of the additional circuit 20 to the power consumption of a certain series arm resonator. The certain series arm resonator is the series arm resonator with the highest power consumption among the multiple series arm resonators S1 to S4. The certain series arm resonator may be the series arm resonator S2 connected to the first node n1 on the output terminal T2 side, or may be another series arm resonator S1, S3, or S4 different from the series arm resonator S2.

The power consumption is the power consumption at the maximum frequency of the pass band of the acoustic wave filter. The power consumption is the power consumption per unit area of each acoustic wave resonator, and is calculated based on electric elements such as the acoustic wave resonator, the electrode parameters of the wiring connected to the electric elements, the power input to the acoustic wave filter, and so forth. The electrode parameters include data such as the material, length, width, and height of the conductor. The area is calculated, for example, as the center-to-center distance in the first direction d1 of two electrode fingers located at the outermost ends of the IDT electrode×the overlap width.

As illustrated in FIG. 7, in Example Embodiment 1, the ratio of the power consumption of the additional circuit 20 is 1/4 with respect to the Comparative Example. Thus, in Example Embodiment 1, the power consumption of the additional circuit 20 can be reduced compared to the Comparative Example.

Next, the attenuation outside the pass band of an acoustic wave filter will be described.

FIG. 8 is a diagram illustrating the attenuation outside the pass band of the acoustic wave filters of Example Embodiment 1 and the Comparative Example.

FIG. 8 illustrates the isolation characteristics in another band of the acoustic wave filter 1, which is a transmission filter. The transmission band of the acoustic wave filter 1 in this example is 1710 MHz to 1785 MHz, and the other band that the acoustic wave filter 1 needs to attenuate is 1805 MHz to 1880 MHz. As illustrated in FIG. 8, the acoustic wave filter 1 can ensure sufficient attenuation in the other band. Thus, in Example Embodiment 1, attenuation in the attenuation band, which is outside the pass band, can be ensured, and the power consumption of the additional circuit 20 can be reduced.

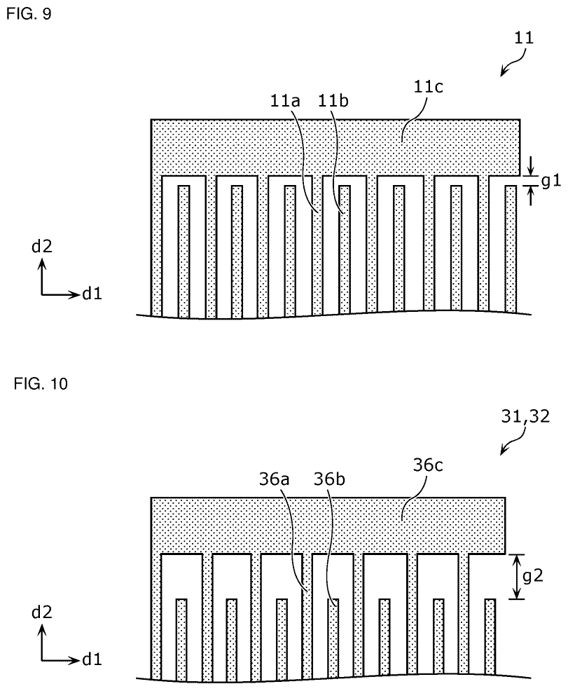

An acoustic wave filter 1 of Modification 1 of Example Embodiment 1 will be described with reference to FIGS. 9 to 11. In Modification 1, an example will be described in which the offset gap of the IDT electrode is larger in the additional circuit 20 than in the filter circuit 10.

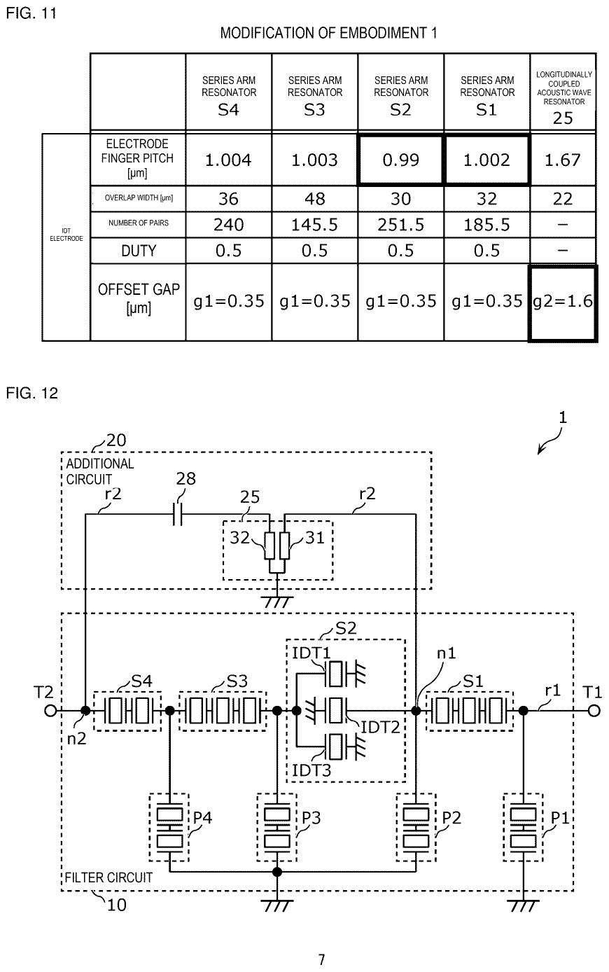

FIG. 9 is a diagram illustrating a portion of the IDT electrode 11 of the filter circuit 10 in Modification 1 of Example Embodiment 1. FIG. 10 is a diagram illustrating a portion of the IDT electrodes 31 and 32 of the additional circuit 20 in Modification 1 of Example Embodiment 1. FIG. 11 is a diagram illustrating electrode parameters of the IDT electrodes 11, 31, and 32 in Modification 1 of Example Embodiment 1.

FIG. 9 illustrates an offset gap g1 of the IDT electrode 11 of the filter circuit 10. The offset gap g1 of the IDT electrode 11 is the distance between the tip of an electrode finger 11b and the busbar electrode 11c facing the tip of the electrode finger 11b. The tip of the electrode finger 11b is the other end on the opposite side from the one end of the electrode finger 11b connected to the busbar electrode 11c. The offset gap g1 is also the distance between the tip of an electrode finger 11a and the busbar electrode 11c facing the tip of the electrode finger 11a (not illustrated).

FIG. 10 illustrates an offset gap g2 of the IDT electrode 31 of the additional circuit 20. The offset gap g2 of the IDT electrode 31 is the distance between the tip of an electrode finger 36b and the busbar electrode 36c facing the tip of the electrode finger 36b. The tip of the electrode finger 36b is the other end on the opposite side from the one end of the electrode finger 36b connected to the busbar electrode 36c. The offset gap g2 is also the distance between the tip of an electrode finger 36a and the busbar electrode 36c facing the tip of the electrode finger 36a (not illustrated).

In Modification 1, the offset gap g2 of the IDT electrodes 31 and 32 of the longitudinally coupled acoustic wave resonator 25 is larger than the offset gap g1 of the IDT electrode 11 of the series arm resonator S2.

With this configuration, the electric field strength between the tips of the electrode fingers and the busbar electrode is smaller in the IDT electrodes 31 and 32 than in the IDT electrode 11. This makes it possible to reduce or prevent melting of the electrode fingers 36a and 36b of the IDT electrodes 31 and 32.

An acoustic wave filter 1 of Modification 2 of Example Embodiment 1 will be described with reference to FIG. 12. In Modification 2, an example in which the series arm resonator S2 is a longitudinally coupled acoustic wave resonator will be described.

FIG. 12 is a circuit configuration diagram illustrating a filter circuit 10 and an additional circuit 20 of the acoustic wave filter 1 according to Modification 2 of Example Embodiment 1.

As illustrated in FIG. 12, the acoustic wave filter 1 includes the filter circuit 10 and the additional circuit 20. The acoustic wave filter 1 also includes an input terminal T1 and an output terminal T2. The configurations of the additional circuit 20, the input terminal T1, and the output terminal T2 are substantially the same as those in Example Embodiment 1.

The filter circuit 10 includes series arm resonators S1, S2, S3, and S4, and parallel arm resonators P1, P2, P3, and P4, which are acoustic wave resonators. The configurations of the series arm resonators S1, S3, and S4, and the parallel arm resonators P1, P2, P3, and P4 are substantially the same as those in Example Embodiment 1.

In Modification 2, the series arm resonator S2, which is connected to the first node n1 and is located closer to the output terminal T2 than the first node n1, is configured as a longitudinally coupled acoustic wave resonator.

Among the multiple series arm resonators, the IDT electrode of the series arm resonator S2, which is connected to the first node n1 and is located closer to the output terminal T2 than the first node n1, includes multiple IDT electrodes.

FIG. 12 illustrates, as an example, three IDT electrodes, namely, IDT1, IDT2, and IDT3, as the multiple IDT electrodes. IDT1, IDT2, and IDT3 are disposed in this order in the first direction. IDT1 and IDT3, which are disposed at odd-numbered positions in the first direction, are connected to the series arm resonator S3, which is located closer to the output terminal T2 than the series arm resonator S2. IDT2, which is disposed at an even-numbered position in the first direction, is connected to the first node n1, which is located closer to the input terminal T1 than the series arm resonator S2.

In this modification, the electrode finger pitch pf of the IDT electrode (IDT2) connected to the first node n1, among the multiple IDT electrodes (IDT1, IDT2, and IDT3) of the certain series arm resonator S2, is smaller than the electrode finger pitch pf of the other series arm resonators S1, S3, and S4 excluding the certain series arm resonator S2.

As described above, by making the electrode finger pitch pf of the IDT electrodes connected to the first node n1, among the multiple IDT electrodes of the series arm resonator S2, smaller than the electrode finger pitch pf of the IDT electrodes of the other series arm resonators S1, S3, and S4 excluding the series arm resonator S2, it is possible to increase the current flowing from the upstream side to the series arm resonator S2 and reduce the current flowing to the additional circuit 20. This makes it possible to reduce the power consumption of the additional circuit 20. In addition, since the power consumption of the additional circuit 20 can be reduced, it is possible to reduce or prevent melting of the electrode fingers 36a and 36b of the IDT electrodes 31 and 32 included in the additional circuit 20.

Alternatively, as described above, by making the electrode finger pitch pf of the IDT electrode connected to the first node n1, among the multiple IDT electrodes of the series arm resonator S2, smaller than the electrode finger pitch pf of the IDT electrode of the series arm resonator S1 connected to the first node n1 and located closer to the input terminal T1 than the first node n1, the current flowing from the upstream side to the series arm resonator S2 can be increased and the current flowing to the additional circuit 20 can be reduced. This makes it possible to reduce the power consumption of the additional circuit 20. In addition, since the power consumption of the additional circuit 20 can be reduced, it is possible to reduce or prevent melting of the electrode fingers 36a and 36b of the IDT electrodes 31 and 32 included in the additional circuit 20.

The electrode finger pitch pf of the IDT2 connected to the first node n1 is derived as follows. The electrode finger pitch pf is calculated by, for example, dividing the center-to-center distance in the first direction between the two electrode fingers located at the outermost ends of the IDT2 by “the total number of electrode fingers of the IDT electrode connected to the first node−the number of IDT electrodes connected to the first node”. In this example, the number of IDT electrodes connected to the first node n1 is 1. In other words, the electrode finger pitch pf of the IDT electrode connected to the first node n1, among the multiple IDT electrodes of the series arm resonator S2, is derived as follows (Equation 5).

Electrode finger pitch=(center-to-center distance in first direction between two electrode fingers located at outermost ends of IDT electrode connected to the first node)/(total number of electrode fingers of IDT electrode connected to first node−number of IDT electrodes connected to first node) (Equation 5)

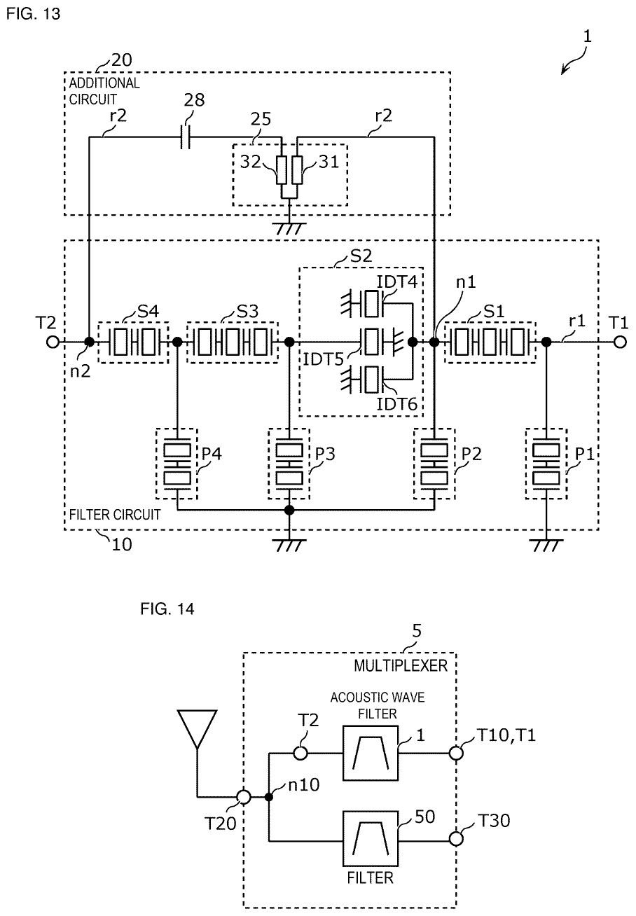

An acoustic wave filter 1 according to Modification 3 of Example Embodiment 1 will be described with reference to FIG. 13. In Modification 3 as well, an example in which the series arm resonator S2 is a longitudinally coupled acoustic wave resonator will be described.

FIG. 13 is a circuit configuration diagram illustrating a filter circuit 10 and an additional circuit 20 of the acoustic wave filter 1 according to Modification 3 of Example Embodiment 1.

As illustrated in FIG. 13, the acoustic wave filter 1 includes the filter circuit 10 and the additional circuit 20. The acoustic wave filter 1 also includes an input terminal T1 and an output terminal T2. The configurations of the additional circuit 20, the input terminal T1, and the output terminal T2 are substantially the same as those in Example Embodiment 1.

The filter circuit 10 includes series arm resonators S1, S2, S3, and S4, and parallel arm resonators P1, P2, P3, and P4, which are acoustic wave resonators. The configurations of the series arm resonators S1, S3, and S4, and the parallel arm resonators P1, P2, P3, and P4 are substantially the same as those in Example Embodiment 1.

In Modification 3, the series arm resonator S2 connected to the first node n1 and located closer to the output terminal T2 than the first node n1 is configured as a longitudinally coupled acoustic wave resonator.

Among the multiple series arm resonators, the IDT electrode of the series arm resonator S2, which is connected to the first node n1 and is located closer to the output terminal T2 than the first node n1, includes multiple IDT electrodes.

FIG. 13 illustrates, as an example, three IDT electrodes, namely, IDT4, IDT5, and IDT6, as the multiple IDT electrodes. IDT4, IDT5, and IDT6 are disposed in this order in the first direction. IDT5, which is disposed at an even-numbered position in the first direction, is connected to the series arm resonator S3, which is located closer to the output terminal T2 than the series arm resonator S2. IDT4 and IDT6, which are disposed at odd-numbered positions in the first direction, are connected to the first node n1, which is located closer to the input terminal T1 than the series arm resonator S2.

In this modification, the electrode finger pitch pf of the IDT electrodes (IDT4 and IDT6) connected to the first node n1, among the multiple IDT electrodes (IDT4, IDT5, and IDT6) of the certain series arm resonator S2, is smaller than the electrode finger pitch pf of the other series arm resonators S1, S3, and S4 excluding the certain series arm resonator S2.

As described above, by making the electrode finger pitch pf of the IDT electrodes connected to the first node n1, among the multiple IDT electrodes of the series arm resonator S2, smaller than the electrode finger pitch pf of the IDT electrodes of the other series arm resonators S1, S3, and S4 excluding the series arm resonator S2, it is possible to increase the current flowing from the upstream side to the series arm resonator S2 and reduce the current flowing to the additional circuit 20. This makes it possible to reduce the power consumption of the additional circuit 20. In addition, since the power consumption of the additional circuit 20 can be reduced, it is possible to reduce or prevent melting of the electrode fingers 36a and 36b of the IDT electrodes 31 and 32 included in the additional circuit 20.

Alternatively, as described above, by making the electrode finger pitch pf of the IDT electrode connected to the first node n1, among the multiple IDT electrodes of the series arm resonator S2, smaller than the electrode finger pitch pf of the IDT electrode of the series arm resonator S1 connected to the first node n1 and located closer to the input terminal T1 than the first node n1, the current flowing from the upstream side to the series arm resonator S2 can be increased and the current flowing to the additional circuit 20 can be reduced. This makes it possible to reduce the power consumption of the additional circuit 20. In addition, since the power consumption of the additional circuit 20 can be reduced, it is possible to reduce or prevent melting of the electrode fingers 36a and 36b of the IDT electrodes 31 and 32 included in the additional circuit 20.

The electrode finger pitch pf of the IDT4 and IDT6 connected to the first node n1 is derived as follows. The electrode finger pitch pf is calculated, for example, by adding together the center-to-center distance in the first direction between the two electrode fingers located at the outermost ends of the IDT4 and the center-to-center distance in the first direction between the two electrode fingers located at the outermost ends of the IDT6, and dividing the sum by the “total number of electrode fingers of the IDT electrodes connected to the first node−the number of IDT electrodes connected to the first node”. In this example, the number of IDT electrodes connected to the first node n1 is 2. That is, the electrode finger pitch pf of the IDT electrodes connected to the first node n1, among the multiple IDT electrodes of the series arm resonator S2, is derived as follows (Equation 6).

Electrode finger pitch=(sum of center-to-center distances in first direction between two electrode fingers located at the outermost ends of IDT electrode in each of multiple IDT electrodes connected to first node)/(total number of electrode fingers of IDT electrodes connected to first node−number of IDT electrodes connected to first node) (Equation 6)

A multiplexer according to Example Embodiment 2 will be described with reference to FIG. 14.

FIG. 14 is a circuit configuration diagram of a multiplexer 5 according to Example Embodiment 2.

The multiplexer 5 is a splitter or multiplexer including a plurality of filters. The multiplexer 5 includes the acoustic wave filter 1, which includes the filter circuit 10 and the additional circuit 20, and another filter 50 different from the acoustic wave filter 1. The multiplexer 5 also includes a first terminal T10 connected to the acoustic wave filter 1, a second terminal T20 connected to both the acoustic wave filter 1 and the other filter 50, and a third terminal T30 connected to the other filter 50. The above-mentioned input terminal T1 corresponds to the first terminal T10. The output terminal T2 is provided between the filter circuit 10 of the acoustic wave filter 1 and a node n10, which is a connection point between the acoustic wave filter 1 and the other filter 50.

The basic configurations of the acoustic wave filter 1, the other filter 50, the first terminal T10, and the second terminal T20 are the same as those in Example Embodiment 1.

For example, a radio-frequency signal of Band 3 (transmission band: 1710 MHz-1785 MHz, reception band: 1805 MHz-1880 MHz) is input to and output from the multiplexer 5. The transmission band of the acoustic wave filter 1 is set to a frequency lower than the reception band of the other filter 50.

As described above, according to the multiplexer 5 including the acoustic wave filter 1 as described above, a multiplexer can be provided in which the power consumption of the additional circuit 20 of the acoustic wave filter 1 is reduced or prevented.

Acoustic wave filters according to example embodiments of the present invention may be configured as follows.

An acoustic wave filter 1 of Example 1 includes the input terminal T1, the output terminal T2, the filter circuit 10 provided on the first path r1 connecting the input terminal T1 and the output terminal T2, and the additional circuit 20 provided on the second path r2 connected in parallel with at least a portion of the first path r1. The additional circuit 20 includes the longitudinally coupled acoustic wave resonator 25. The filter circuit 10 includes a plurality of series arm resonators S1 to S4 provided on the first path r1, and one or more parallel arm resonators P1 to P4 provided on paths connecting the first path r1 to ground. Each of the plurality of series arm resonators S1 to S4 and the one or more parallel arm resonators P1 to P4 includes the IDT electrode 11. The first node n1 and the second node n2, which are connection points between the first path r1 and the second path r2, are provided on both outer sides of one or more of the series arm resonators (e.g., S2 to S4) disposed on the first path r1, and the first node n1 is provided closer to the input terminal T1 than the second node n2. Among the plurality of series arm resonators S1 to S4, a certain series arm resonator (e.g., S2) that is connected to the first node n1 and is located closer to the output terminal T2 than the first node n1 includes one or more IDT electrodes. The electrode finger pitch pf of the IDT electrode 11 connected to the first node n1, among the one or more IDT electrodes 11, is smaller than the electrode finger pitch pf of the IDT electrodes 11 of the other series arm resonators (e.g., S1, S3, and S4) excluding the certain series arm resonator S2.

Thus, by making the electrode finger pitch pf of the IDT electrode 11 connected to the first node n1 of the series arm resonator S2 smaller than the electrode finger pitch pf of the IDT electrodes 11 of the other series arm resonators S1, S3, and S4, the current flowing from the upstream side to the series arm resonator S2 can be increased and the current flowing to the additional circuit 20 can be reduced. This makes it possible to reduce the power consumption of the additional circuit 20. In addition, since the power consumption of the additional circuit 20 can be reduced, it is possible to reduce or prevent melting of the electrode fingers 36a and 36b of the IDT electrodes 31 and 32 included in the additional circuit 20.

The acoustic wave filter 1 of Example 2 is the acoustic wave filter of Example 1, in which the first node n1 may be located between two adjacent series arm resonators (e.g., S1 and S2) on the first path r1.

This makes it easier for a current to flow from the first node n1 to the series arm resonator S2 located on the output terminal T2 side, and prevents the current flowing from the first node n1 to the additional circuit 20 from becoming excessively large. This makes it possible to reduce the power consumption of the additional circuit 20.

The acoustic wave filter 1 of Example 3 includes the input terminal T1 and the output terminal T2, the filter circuit 10 provided on the first path r1 connecting the input terminal T1 and the output terminal T2, and the additional circuit 20 provided on the second path r2 connected in parallel with at least a portion of the first path r1. The additional circuit 20 includes the longitudinally coupled acoustic wave resonator 25. The filter circuit 10 includes a plurality of series arm resonators S1 to S4 provided on the first path r1, and one or more parallel arm resonators P1 to P4 provided on paths connecting the first path r1 to ground. Each of the plurality of series arm resonators S1 to S4 and the one or more parallel arm resonators P1 to P4 includes the IDT electrode 11. The first node n1 and the second node n2, which are connection points between the first path r1 and the second path r2, are provided on both outer sides of one or more of the series arm resonators (e.g., S2 to S4) disposed on the first path r1, and the first node n1 is provided closer to the input terminal T1 than the second node n2 and is located between two adjacent series arm resonators (e.g., S1 and S2) on the first path r1. Among the two series arm resonators S1 and S2, a certain series arm resonator S2 located closer to the output terminal T2 than the first node n1 includes one or more IDT electrodes 11. The electrode finger pitch pf of the IDT electrode 11 connected to the first node n1, among the one or more IDT electrodes 11, is smaller than the electrode finger pitch pf of the IDT electrode 11 of the series arm resonator S1 connected to the first node n1 and located closer to the input terminal T1 than the first node n1.

Thus, by making the electrode finger pitch pf of the IDT electrode 11 of the series arm resonator S2 connected to the first node n1 smaller than the electrode finger pitch pf of the IDT electrode 11 of the series arm resonator S1 located closer to the input terminal T1 than the first node n1, the current flowing from the upstream side to the series arm resonator S2 can be increased and the current flowing to the additional circuit 20 can be reduced. This makes it possible to reduce the power consumption of the additional circuit 20. In addition, since the power consumption of the additional circuit 20 can be reduced, it is possible to reduce or prevent melting of the electrode fingers 36a and 36b of the IDT electrodes 31 and 32 included in the additional circuit 20.

The acoustic wave filter 1 of Example 4 is the acoustic wave filter of Example 3, in which the electrode finger pitch pf of the IDT electrode 11 connected to the first node n1, among the one or more IDT electrodes 11, may be smaller than the electrode finger pitch pf of the IDT electrodes 11 of the other series arm resonators S1, S3, and S4 excluding the certain series arm resonator S2.

This makes it easier for a current to flow from the first node n1 to the series arm resonator S2 located on the output terminal T2 side, and prevents the current flowing from the first node n1 to the additional circuit 20 from becoming excessively large. This makes it possible to reduce the power consumption of the additional circuit 20.

The acoustic wave filter 1 of Example 5 is the acoustic wave filter of any one of Examples 1 to 4, in which the additional circuit 20 may further include the capacitance element 28. The capacitance element 28 may be provided on the second path r2 between the longitudinally coupled acoustic wave resonator 25 and the second node n2.

This allows, for example, a large current to be prevented from instantaneously flowing from the output terminal T2 side to the longitudinally coupled acoustic wave resonator 25. This makes it possible to reduce or prevent melting of the electrode fingers 36a and 36b of the IDT electrodes 31 and 32 included in the additional circuit 20.

The acoustic wave filter 1 of Example 6 is the acoustic wave filter of any one of Examples 1 to 5, in which the IDT electrodes 31 and 32 of the longitudinally coupled acoustic wave resonator 25 may have a smaller overlap width than the IDT electrode 11 of the series arm resonator S2 that is connected to the first node n1 and is located closer to the output terminal T2 than the first node n1.

This can reduce the impedance of the IDT electrodes 31 and 32 of the longitudinally coupled acoustic wave resonator 25. This makes it possible to reduce or prevent melting of the electrode fingers 36a and 36b of the IDT electrodes 31 and 32 included in the additional circuit 20.

The acoustic wave filter 1 of Example 7 is the acoustic wave filter of any one of Examples 1 to 6, in which the IDT electrodes 11, 31, and 32 each include a pair of comb-shaped electrodes, and each of the pair of comb-shaped electrodes includes a plurality of electrode fingers and a busbar electrode that connects one ends of the plurality of electrode fingers to each other. An offset gap is provided between the tip of each electrode finger and the busbar electrode facing the tip of the electrode finger. The offset gap g2 of the IDT electrodes 31 and 32 of the longitudinally coupled acoustic wave resonator 25 may be larger than the offset gap g1 of the IDT electrode 11 of the series arm resonator S2 connected to the first node n1 and located closer to the output terminal T2 than the first node n1.

This configuration allows the electric field strength between the tips of the electrode fingers 36a (or 36b) of the IDT electrodes 31 and 32 and the busbar electrodes 36c to be reduced. This makes it possible to reduce or prevent melting of the electrode fingers 36a and 36b of the IDT electrodes 31 and 32.

The multiplexer 5 of Example 8 includes the acoustic wave filter 1 of any one of Examples 1 to 7 and the other filter 50 including a circuit different from the filter circuit 10.

This makes it possible to provide the multiplexer 5 that ensures the attenuation in the pass band of the other filter 50 and reduces or prevents the power consumption of the acoustic wave filter 1.

Acoustic wave filters according to example embodiments of the present invention have been described above with reference to example embodiments. However, in the present invention, other example embodiments realized by combining any of the components in the above example embodiments, modifications that are obtained by making various modifications devised by those skilled in the art to the above example embodiments without departing from the spirit of the present invention, and radio-frequency front-end circuits and communication devices that include the acoustic wave filters or multiplexers according to example embodiments of the present invention are also included in the present invention.

An example is described above in which the longitudinally coupled acoustic wave resonator 25 includes two IDT electrodes, but the present invention is not limited to this, and the number of IDT electrodes may be three or more.

In addition, an example of a multiplexer that includes two filters is described above. However, example embodiments of the present invention can also be applied to, for example, a triplexer in which the antenna terminals of three filters are connected together to provide a common connection, or a hexaplexer in which the antenna terminals of six filters are connected together to provide a common connection. In other words, it is sufficient that the multiplexer include at least two filters.

Furthermore, the other filter 50 is not limited to the above-described filter configuration, and may be appropriately designed in accordance with the required filter characteristics, etc. Specifically, the other filter 50 may have a longitudinally coupled filter structure or a ladder filter structure. Furthermore, each resonator of the other filter 50 is not limited to a SAW resonator, and may be a bulk acoustic wave (BAW) resonator, for example. Furthermore, the other filter 50 may be configured without using a resonator, and may be, for example, an LC resonator filter or a dielectric filter.

An example is described above in which the piezoelectric substrate 100 includes a high-acoustic-velocity support substrate, a low-acoustic-velocity film, and a piezoelectric layer, but the configurations of the high-acoustic-velocity support substrate, the low-acoustic-velocity film, and the piezoelectric layer may be as described below.

The piezoelectric layer includes, for example, θ° Y-cut X-propagation LiTaO₃ piezoelectric single crystal or piezoelectric ceramic (lithium tantalate single crystal or a ceramic which is cut along a plane with an axis rotated θ° with respect to the X axis serving as the center axis from the Y axis in the Z-axis direction as a normal line, in which the surface acoustic waves propagate in the X-axis direction).

The high-acoustic-velocity support substrate is a substrate that supports the low-acoustic-velocity film, the piezoelectric layer, and the electrode 110. The high-acoustic-velocity support substrate is, furthermore, a substrate in which the acoustic velocity of bulk waves in the high-acoustic-velocity support substrate is higher than that of acoustic waves such as surface acoustic waves or boundary waves that propagate in the piezoelectric layer, and functions so that the surface acoustic waves are confined to the part where the piezoelectric layer and the low-acoustic-velocity film are stacked, and do not leak to below the high-acoustic-velocity support substrate.

The high-acoustic-velocity support substrate is, for example, a silicon substrate. The material of the high-acoustic-velocity support substrate may be, for example, a piezoelectric material such as aluminum nitride, lithium tantalate, lithium niobate, or quartz crystal, a ceramic material such as alumina, sapphire, magnesia, silicon nitride, silicon carbide, zirconia, cordierite, mullite, steatite, forsterite, spinel, or sialon, a dielectric material such as aluminum oxide, silicon oxynitride, diamond-like carbon (DLC), or diamond, or a semiconductor material such as silicon, or a material mainly including any of the above materials. Spinel includes an aluminum compound containing oxygen and one or more elements selected from Mg, Fe, Zn, Mn, etc. Examples of spinel include MgAl₂O₄, FeAl₂O₄, ZnAl₂O₄, and MnAl₂O₄.

The low-acoustic-velocity film is a film in which the acoustic velocity of bulk waves in the low-acoustic-velocity film is lower than the acoustic velocity of acoustic waves propagating through the piezoelectric layer, and is disposed between the piezoelectric layer and the high-acoustic-velocity support substrate. Leaking of the energy of surface acoustic waves to outside the IDT electrodes is reduced or prevented by this structure and the characteristic that energy is essentially concentrated in a medium in which acoustic waves have a low acoustic velocity.

The low-acoustic-velocity film is, for example, a film mainly including silicon dioxide (SiO₂). The material of the low-acoustic-velocity film is not limited to the above materials, and may be, for example, a dielectric material such as glass, silicon oxide, silicon oxynitride, lithium oxide, tantalum oxide, or a compound of silicon oxide with fluorine, carbon, or boron added, or a material mainly including any of the above materials.

According to the multilayer of structure 41 the piezoelectric substrate 100, the Q factor of the acoustic wave resonator at the resonant frequency and the anti-resonant frequency can be significantly increased compared to a structure using a piezoelectric substrate 100 having a single layer structure. That is, a surface acoustic wave resonator having a high Q factor can be provided, and therefore, it is possible to provide a filter having smaller insertion loss using the surface acoustic wave resonator.

The high-acoustic-velocity support substrate may have a structure in which a support substrate and a high-acoustic-velocity film, in which the acoustic velocity of bulk waves propagating through the piezoelectric layer is higher than that of acoustic waves such as the surface acoustic waves or boundary waves propagating through the piezoelectric layer, are stacked.

In the case of this multilayer structure, the material of the support substrate may be a piezoelectric material such as sapphire, lithium tantalate, lithium niobate, or quartz crystal, various ceramic materials such as alumina, magnesia, silicon nitride, aluminum nitride, silicon carbide, zirconia, cordierite, mullite, steatite, or forsterite, a dielectric material such as glass, or a semiconductor such as silicon or gallium nitride, or a resin substrate.

The material of the high-acoustic-velocity film may be, for example, a piezoelectric material such as aluminum nitride, lithium tantalate, lithium niobate, or quartz crystal, a ceramic such as alumina, sapphire, magnesia, silicon nitride, silicon carbide, zirconia, cordierite, mullite, steatite, forsterite, spinel, or sialon, a dielectric material such as aluminum oxide, silicon oxynitride, diamond-like carbon (DLC), or diamond, or a semiconductor such as silicon, or a material containing any of the above materials as a main component. Spinel includes an aluminum compound containing oxygen and one or more elements selected from Mg, Fe, Zn, Mn, etc. Examples of spinel include MgAl₂O₄, FeAl₂O₄, ZnAl₂O₄, and MnAl₂O₄.

The materials and so forth of the layers exemplified in the multilayer structure of the piezoelectric substrate 100 are merely examples, and may be changed depending on, for example, the characteristics to be emphasized among the required radio-frequency propagation characteristics.

In the above description, the piezoelectric substrate 100 is described as a substrate exhibiting piezoelectricity, but the piezoelectric substrate may be a piezoelectric substrate including a single layer of a piezoelectric layer. In this case, the piezoelectric substrate includes, for example, a piezoelectric single crystal of LiTaO₃ or another piezoelectric single crystal such as LiNbO₃. The piezoelectric substrate 100 on which the IDT electrodes are provided may be defined by a piezoelectric layer, or may have a structure in which a piezoelectric layer is stacked on a support substrate as long as the piezoelectric substrate exhibits piezoelectricity. The cut angle of the piezoelectric substrate 100 according to the above example embodiments is not limited. In other words, the multilayer structure, materials, and thicknesses may be changed as appropriate depending on the required bandpass characteristics, etc. of the acoustic wave filter, and substantially the same effects can be achieved even with a surface acoustic wave filter using a LiTaO₃ piezoelectric substrate, a LiNbO₃ piezoelectric substrate, or the like having a cut angle other than the cut angle described in the above example embodiments.

Example embodiments of the present invention can be widely used in communication devices such as mobile phones as a multiplexer, a front-end circuit, and a communication device including an acoustic wave filter.

While example embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. An acoustic wave filter comprising:
an input terminal;
an output terminal;
a filter circuit on a first path connecting the input terminal and the output terminal; and
an additional circuit on a second path connected in parallel with at least a portion of the first path; wherein
the additional circuit includes a longitudinally coupled acoustic wave resonator;
the filter circuit includes a plurality of series arm resonators on the first path and one or more parallel arm resonators on a path connecting the first path and ground;
each of the plurality of series arm resonators and the one or more parallel arm resonators includes an IDT electrode;
a first node and a second node, which are connection points between the first path and the second path, are provided on both outer sides of one or more of the series arm resonators on the first path;
the first node is closer to the input terminal than the second node;
one of the plurality of series arm resonators that is connected to the first node and is located closer to the output terminal than the first node includes one or more IDT electrodes; and
an electrode finger pitch of one of the one or more IDT electrodes that is connected to the first node is smaller than an electrode finger pitch of IDT electrodes of other series arm resonators excluding the one of the plurality of series arm resonators.

2. The acoustic wave filter according to claim 1, wherein the first node is located between two of the series arm resonators that are adjacent to each other on the first path.

3. The acoustic wave filter according to claim 1, wherein the additional circuit further includes a capacitance element on the second path between the longitudinally coupled acoustic wave resonator and the second node.

4. The acoustic wave filter according to claim 1, wherein an IDT electrode of the longitudinally coupled acoustic wave resonator has a smaller overlap width than the IDT electrode of the series arm resonator connected to the first node and located closer to the output terminal than the first node.

5. The acoustic wave filter according to claim 1, wherein
the IDT electrode includes a pair of comb-shaped electrodes;
each of the pair of comb-shaped electrodes includes a plurality of electrode fingers and a busbar electrode connecting one ends of the plurality of electrode fingers to each other;
an offset gap is provided between tips of the electrode fingers and the busbar electrode facing the tips of the electrode fingers; and
the offset gap of an IDT electrode of the longitudinally coupled acoustic wave resonator is larger than the offset gap of the IDT electrode of the series arm resonator connected to the first node and located closer to the output terminal than the first node.

6. The acoustic wave filter according to claim 1, wherein the longitudinally coupled acoustic wave resonator includes two IDT electrodes or includes three or more IDT electrodes.

7. A multiplexer comprising:
the acoustic wave filter according to claim 1; and
another filter including a circuit different from the filter circuit.

8. The multiplexer according to claim 7, wherein the multiplexer is a triplexer including antenna terminals of three filters connected together to provide a common connection, or is a hexaplexer including antenna terminals of six filters connected together to provide a common connection.

9. The multiplexer according to claim 7, wherein the other filter has a longitudinally coupled filter structure or a ladder filter structure, or is an LC resonator filter or a dielectric filter.

10. The multiplexer according to claim 7, wherein the other filter is a surface acoustic resonator filter or a bulk acoustic wave filter.

11. An acoustic wave filter comprising:
an input terminal;
an output terminal;
a filter circuit on a first path connecting the input terminal and the output terminal; and
an additional circuit on a second path connected in parallel with at least a portion of the first path; wherein
the additional circuit includes a longitudinally coupled acoustic wave resonator;
the filter circuit includes a plurality of series arm resonators on the first path and one or more parallel arm resonators on a path connecting the first path and ground;
each of the plurality of series arm resonators and the one or more parallel arm resonators includes an IDT electrode;
a first node and a second node, which are connection points between the first path and the second path, are provided on both outer sides of one or more of the series arm resonators on the first path;
the first node is closer to the input terminal than the second node and is located between two of the series arm resonators that are adjacent to each other on the first path;
one of the two series arm resonators that is located closer to the output terminal than the first node includes one or more IDT electrodes; and
an electrode finger pitch of one of the one or more IDT electrodes that is connected to the first node is smaller than an electrode finger pitch of an IDT electrode of a series arm resonator connected to the first node and located closer to the input terminal than the first node.

12. The acoustic wave filter according to claim 11, wherein the electrode finger pitch of the IDT electrode of the one of the one or more IDT electrodes that is connected to the first node is smaller than an electrode finger pitch of IDT electrodes of other series arm resonators excluding the one of the two series arm resonators.

13. The acoustic wave filter according to claim 11, wherein the additional circuit further includes a capacitance element on the second path between the longitudinally coupled acoustic wave resonator and the second node.

14. The acoustic wave filter according to claim 11, wherein an IDT electrode of the longitudinally coupled acoustic wave resonator has a smaller overlap width than the IDT electrode of the series arm resonator connected to the first node and located closer to the output terminal than the first node.

15. The acoustic wave filter according to claim 11, wherein
the IDT electrode includes a pair of comb-shaped electrodes;
each of the pair of comb-shaped electrodes includes a plurality of electrode fingers and a busbar electrode connecting one ends of the plurality of electrode fingers to each other;
an offset gap is provided between tips of the electrode fingers and the busbar electrode facing the tips of the electrode fingers; and
the offset gap of an IDT electrode of the longitudinally coupled acoustic wave resonator is larger than the offset gap of the IDT electrode of the series arm resonator connected to the first node and located closer to the output terminal than the first node.

16. The acoustic wave filter according to claim 11, wherein the longitudinally coupled acoustic wave resonator includes two IDT electrodes or includes three or more IDT electrodes.

17. A multiplexer comprising:
the acoustic wave filter according to claim 1; and
another filter including a circuit different from the filter circuit.

18. The multiplexer according to claim 17, wherein the multiplexer is a triplexer including antenna terminals of three filters connected together to provide a common connection, or is a hexaplexer including antenna terminals of six filters connected together to provide a common connection.

19. The multiplexer according to claim 17, wherein the other filter has a longitudinally coupled filter structure or a ladder filter structure, or is an LC resonator filter or a dielectric filter.

20. The multiplexer according to claim 17, wherein the other filter is a surface acoustic resonator filter or a bulk acoustic wave filter.
